(19) United States
(12) Patent Application Publication
(10) Pub. No.: US 2012/0192794 A1
(43) Pub. Date: Aug. 2, 2012

(54) SOURCE SUPPLYING APPARATUS AND FILM FORMING APPARATUS

(75) Inventors: Hidetoshi Kinoshita, Nirasaki (JP); Yasushi Morita, Nirasaki (JP)

(73) Assignee: TOKYO ELECTRON LIMITED, Tokyo (JP)

(21) Appl. No.: 13/362,132

(22) Filed: Jan. 31, 2012

(30) Foreign Application Priority Data
Feb. 1, 2011 (JP) 2011-019392

(51) Int. Cl. C23C 16/46; F24H 9/00

(52) U.S. Cl. 118/725; 392/394

(57) ABSTRACT

There is provided a source supplying apparatus 62 including: a vertically elongated source containing body 64 having an outer peripheral surface formed as a liquid source flow surface 90 for a liquid source to flow thereon; a liquid source storage member 66 provided at a position of the source containing body in a height direction to store the liquid source, and configured for the liquid source to flow to the liquid source flow surface by wettability; and a heating device 68 provided within the source containing body, and configured to heat the liquid source storage member to allow the liquid source to have wettability and to heat a leading end of the source containing body to an evaporating temperature of the liquid source.

### CROSS-REFERENCE TO RELATED APPLICATION

This application claims the benefit of Japanese Patent Application No. 2011-019392 filed on Feb. 1, 2011, the entire disclosures of which are incorporated herein by reference.

### FIELD OF THE INVENTION

The present disclosure relates to a film forming apparatus and a source supplying apparatus for manufacturing a compound semiconductor.

### BACKGROUND OF THE INVENTION

In general, in order to manufacture, e.g., a LED (Light Emitting Diode) device or a power transistor device for power control, there has been a tendency to use a compound semiconductor made of a compound of two or more kinds of elements because the compound semiconductor enables a high current flow, as compared to a typical semiconductor device using an IV group element such as Si or Ge.

In order to manufacture such a compound semiconductor, a MBE (Molecular Beam Epitaxy) method, for example, has been employed (see, for example, Patent Document 1). In a film forming apparatus using this MBE method, a source container is accommodated in a processing chamber maintained in a high vacuum, and a semiconductor wafer is held on a ceiling portion within the processing chamber such that a film forming target surface of the semiconductor wafer faces downward (i.e., in a face-down state). In this film forming apparatus, a source stored in the source container is heated and evaporated by irradiating a molecular beam to the source, so that a compound semiconductor is formed on the film forming target surface of the semiconductor wafer facing downward. Here, considering that the source stored in the source container is in a liquid phase, the source container needs to be installed in the processing chamber such that a liquid surface faces upward. Thus, inevitably, the wafer needs to be held in the face-down state as described above. Here, for example, when nitrogen is used as a part of elements, in case of forming GaN as a compound semiconductor, an ammonia gas or a nitrogen gas is supplied into the processing chamber as a source gas.
Patent Document 1: Japanese Patent Laid-open Publication No. H10-027755

In the aforementioned film forming apparatus, however, a holding device for holding the semiconductor wafer in the face-down state at the ceiling portion of the processing chamber has a very complicated structure. Further, since the wafer is heated to a high temperature ranging from about 800° C. to about 1200° C., the holding device itself needs to have a heat-resistance structure, raising a structural problem.

### BRIEF SUMMARY OF THE INVENTION

In view of the foregoing problems, illustrative embodiments provide a source supplying apparatus and a film forming apparatus capable of forming a thin film of a compound semiconductor on a surface of a processing target object held in a face-up state.

In accordance with one aspect of an illustrative embodiment, there is provided a source supplying apparatus for supplying a source used for forming a compound semiconductor. The source supplying apparatus includes a vertically elongated source containing body having an outer peripheral surface formed as a liquid source flow surface capable of allowing a liquid source to flow thereon; a liquid source storage member provided at a position of the source containing body in a height direction to store therein the liquid source, and configured to allow the liquid source to flow to the liquid source flow surface by wettability; and a heating device provided within the source containing body, and configured to heat the liquid source storage member so as to allow the liquid source to have wettability and to heat a leading end of the source containing body to an evaporating temperature of the liquid source.

In this configuration, the liquid source stored in the liquid source storing member of the vertically elongated source containing body is allowed to flow on the liquid source flow surface by its wettability toward the leading end of the source containing body heated by the heating device to a temperature higher than the evaporating temperature of the liquid source. Accordingly, without the complicate structure of the apparatus, it is possible to evaporate or diffuse the liquid source from the leading end of the source containing body while preventing the liquid source from dripping down as droplets.

In accordance with another aspect of an illustrative embodiment, there is provided a film forming apparatus for forming, on a surface of a processing target object, a thin film of a compound semiconductor containing plural kinds of elements. The film forming apparatus includes an evacuable processing chamber; a holding device for holding the processing target object in a face-up state within the processing chamber; a heating device configured to heat the processing target object; and a single or a plurality of source supplying apparatuses described in the above.

Since the source supplying apparatus as stated above is used, it is possible to form a thin film of a compound semiconductor on the processing target object while holding the processing target object in a face-up state.

In accordance with the source supplying apparatus and the film forming apparatus of the illustrative embodiments, the following advantages can be achieved.

Since the liquid source stored in the liquid source storing member of the vertically elongated source containing body is allowed to flow on the liquid source flow surface by its wettability toward the leading end of the source containing body heated by the heating device to a temperature higher than the evaporating temperature of the liquid source, it is possible to evaporate or diffuse the liquid source from the leading end of the source containing body while preventing the liquid source from dripping down as droplets, without the complicate structure of the apparatus.

Since the source supplying apparatus as stated above is used, it is possible to form a thin film of a compound semiconductor on the processing target object while holding the processing target object in a face-up state.

### BRIEF DESCRIPTION OF THE DRAWINGS

Non-limiting and non-exhaustive embodiments will be described in conjunction with the accompanying drawings. Understanding that these drawings depict only several embodiments in accordance with the disclosure and are, therefore, not to be intended to limit its scope, the disclosure will be described with specificity and detail through use of the accompanying drawings, in which:

FIG. 1 is a configuration view illustrating a film forming apparatus using a source supplying apparatus in accordance with an illustrative embodiment;

FIG. 2 is an enlarged cross sectional view illustrating major parts of the source supplying apparatus in accordance with the illustrative embodiment;

FIG. 3 is an enlarged cross sectional view illustrating a source containing body (illustration of a heater and a thermocouple is omitted) of the source supplying apparatus in accordance with the illustrative embodiment; and

FIG. 4 is a partial configuration view illustrating a part of a modification example of the film forming apparatus in accordance with the illustrative embodiment.

### DETAILED DESCRIPTION OF THE INVENTION

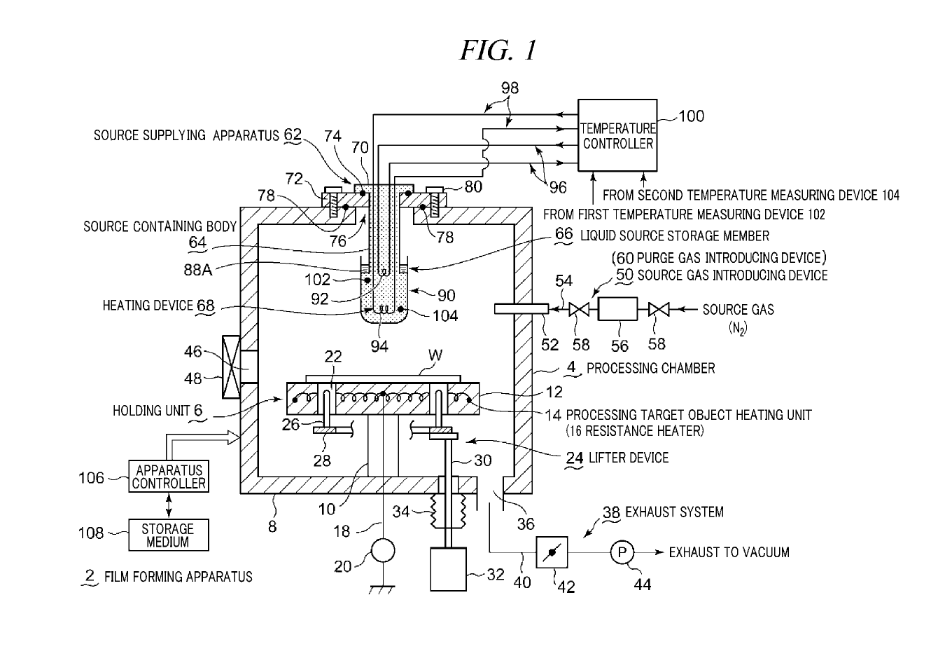

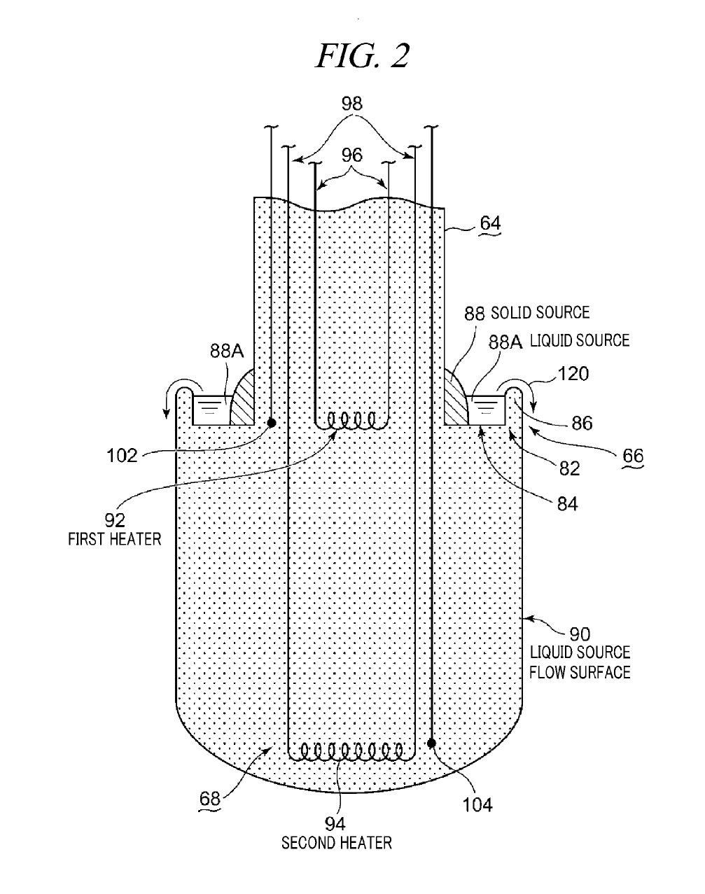

Hereinafter, a source supplying apparatus and a film forming apparatus in accordance with an illustrative embodiment will be described in detail with reference to the accompanying drawings. FIG. 1 is a configuration view illustrating a film forming apparatus using a source supplying apparatus in accordance with an illustrative embodiment, and FIG. 2 is an enlarged cross sectional view illustrating major parts of the source supplying apparatus in accordance with the illustrative embodiment. Here, an example of forming a thin film of gallium nitride (GaN) as a compound semiconductor will be described.

As illustrated in FIG. 1, a film forming apparatus 2 in accordance with an illustrative embodiment includes a box-shaped processing chamber 4 made of, but not limited to, aluminum, aluminum alloy, or stainless steel. In the processing chamber 4 is provided a holding unit 6 for holding a semiconductor wafer W serving as a processing target object in a so-called face-up state. To elaborate, the holding unit 6 includes a mounting table 12 placed on an upper end of a supporting column 10 uprightly standing from a bottom 8 of the processing chamber 4. The wafer W is mounted on the mounting table 12 in a face-up state. Here, the “face-up state” means that a film forming target surface of the wafer W faces upward. A processing target object heating unit 14 is provided within the mounting table 12. By way of non-limiting example, the processing target object heating unit 14 includes a resistance heater 16, and is provided over the substantially entire surface of the mounting table 12 to heat the wafer W.

The supporting column 10 and the mounting table 12 are made of a heat resistant material such as ceramic, quartz, or graphite. By way of example, aluminum nitride, silicon carbide, or alumina may be used as the ceramic material. The resistance heater 16 is connected with a heater power supply 20 via a power feed line 18. The heater power supply 20 is capable of controlling a temperature of the resistance heater 16. Here, the resistance heater 16 may be divided into a multiple number of zones in concentric shapes, and temperatures of the respective zones may be controlled independently.

The mounting table 12 has multiple, e.g., three pin holes 22 through which lifter pins are inserted. The pin holes 22 are formed at a regular interval along the periphery of the mounting table 12. In the shown example, only two pin holes 22 are shown for the simplicity of illustration. Provided under the mounting table 12 is a lifter device 24 for loading and unloading the wafer W. To be specific, the lifter device 24 has lifter pins 26 respectively inserted through the pin holes 22, and a lower end of each lifer pin 26 is supported on an elevation plate 28 formed in, e.g., an arc shape. The elevation plate 28 is supported on an upper end of an elevation rod 30 that penetrates the bottom 8 of the processing chamber 4.

A lower end of the elevation rod 30 is connected to an actuator 32 that is configured to move the elevation rod up and down with a certain stroke. Further, an extensible/contractible bellows 34 made of metal is airtightly provided at a portion of the bottom 8 penetrated by the elevation rod 30. Accordingly, the elevation rod 30 can be moved up and down while the inside of the processing chamber 4 is kept airtight. With this configuration, when the wafer W is loaded or unloaded, the lifter pins 26 are moved up and down so that the wafer W is lifted up or lowered down.

An exhaust port 36 is formed in the bottom 8 of the processing chamber 4, and an exhaust system 38 configured to exhaust an atmosphere within the processing chamber 4 is connected with the exhaust port 36. To elaborate, the exhaust system 38 has an exhaust path 40 connected to the exhaust port 36. On the exhaust path 40, a pressure control valve 42 and a vacuum pump 44 for controlling an internal pressure of the processing chamber 4 are arranged in sequence from an upstream side of the exhaust path 40 toward a downstream side thereof. Accordingly, the inside of the processing chamber 4 can be evacuated while its internal pressure is controlled. Further, actually, the vacuum pump 44 is composed of, e.g., a combination of a turbo molecular pump and a dry pump. Therefore, the vacuum pump 44 is capable of making a high vacuum state.

Moreover, a loading/unloading port 46 through which the wafer W is loaded and unloaded is formed on a sidewall of the processing chamber 4. A gate valve 48 configured to be opened and closed airtightly is provided at the loading/unloading port 46. Further, provided at the processing chamber 4 is a source gas introducing device 50 configured to supply a source gas containing one of plural elements composing a compound semiconductor to be formed in the processing chamber 4.

The source gas introducing device 50 includes a gas nozzle 52 inserted through the sidewall of the processing chamber 4, and a gas passage 54 is connected to the gas nozzle 52. The gas passage 54 is provided with a flow rate controller 56, such as a mass flow controller, and an opening/closing valve 58 in sequence. Accordingly, a source gas can be supplied when necessary while its flow rate is controlled. Here, as mentioned above, since GaN is formed as a thin film of a compound semiconductor, a gas containing nitrogen (N), e.g., a nitrogen gas (N₂) is used as the source gas.

In case that the source gas introducing device 50 is used to supply the N₂ gas, the source gas introducing device also serves as a purge gas introducing device 60 and supplies the N₂ gas as a purge gas when the atmosphere in the processing chamber 4 is exhausted. Besides the N₂ gas, a rare gas such as Ar or He may be used as the purge gas.

A source supplying apparatus 62 in accordance with an illustrative embodiment is provided in the processing chamber. To elaborate, the source supplying apparatus 62 mainly includes a source containing body 64, a liquid source storage member 66, and a heating device 68. The source containing body 64 is vertically elongated and has a peripheral surface on which a liquid can flow. The liquid source storage member 66 is provided on the way of the source containing body 64 in a height direction. Further, the liquid source storage member 66 stores therein a liquid liquefied from a source, i.e., a liquid source, and allows the liquid source to flow little by little. The heating device 68 is configured to heat the source containing body 64.

To be more specific, the source containing body 64 is made of a heat resistant material such as ceramic, quartz coated with pyrolytic boron nitride (PBN), or graphite in a substantially circular column shape or a cylinder shape having a bottom. In the present embodiment, the source containing body 64 is formed in an approximately circular column shape. A larger-diameter flange 70 is provided at an upper end of the source containing body 64. The source containing body 64 is inserted through an opening of a mounting plate 72 and is airtightly fastened between a top surface of the mounting plate 72 and the flange 70 via a sealing member 74 such as an O-ring or a metal seal.

Further, a mounting hole 76 is provided at a ceiling portion of the processing chamber 4. The source containing body 64 is inserted through the mounting hole 76 in a vertical direction toward the inside of the processing chamber 4. The mounting plate 72 is detachably and airtightly fastened to a ceiling wall of the processing chamber 4 by bolts 80 via a sealing member 78 such as an O-ring provided between a top surface of the ceiling wall at an edge portion of the mounting hole 76 and the mounting plate 72. Since a lower portion of the circular column-shaped source containing body 64 is heated to a very high temperature, the source containing body 64 is set to have a length of, e.g., about 20 cm to about 30 cm so as to prevent an excessive temperature rise of the ceiling portion of the processing chamber 4.

Referring to FIG. 2, the lower portion of the source containing body 64 has a step-shaped portion 82 such that a diameter of the lower portion of the source containing body is larger than an upper portion thereof. The liquid source storage member 66 is formed at this step-shaped portion 82. The liquid source storage member 66 has a liquid source storing recess 84 formed in a ring shape along the periphery of the source containing body 64. An outer peripheral end of the liquid source storing recess 84 is protruded upward to serve as a liquid source storage dam 86. That is, the liquid source storing recess 84 is formed as a ring-shaped groove so as to accommodate therein a solid source 88 and a liquid source 88A produced by melting the solid source 88. As the solid source 88, gallium (Ga) may be used, as mentioned above.

An upper end of the liquid source storage dam 86 is formed to have a curved surface having an arc-shaped or elliptical cross section so as to allow the liquid source 88A to easily flow out by wettability. A surface of the liquid source storage dam 86 and an entire surface of the source containing body 64 positioned below the surface of the liquid source storage dam 86 serve as a liquid source flow surface 90 allowing the liquid source 88A to flow thereon by wettability.

It may be desirable to, for example, polish the liquid source flow surface 90, thus allowing the liquid source 88A to flow uniformly on the liquid source flow surface 90. Further, it may be also possible to form fine irregularities of opaque glass shape on the liquid source flow surface 90 by performing a blast process or the like. Especially, it may be desirable to form a PBN coating layer on the liquid source flow surface 90. It may be advantageous to form the PBN coating layer because PBN is stable at a high temperature, i.e., neither evaporated nor pyrolyzed even at a temperature of about 1200° C. By covering the source containing body 64 with such a stable coating layer, evaporation of components from the source containing body 64 can be prevented.

Furthermore, a lower end portion of the source containing body 64 is formed to have a curved surface having an arc-shaped or elliptical cross section and is configured to allow the liquid source 88A flowing thereon to be evaporated without falling down or dripping down as droplets. A length between the liquid source storage member 66 and a leading end of the source containing body 64 is set to be long enough, e.g., about 10 cm to about 15 cm so as to prevent the liquid source 88A from dripping down.

The heating device 68 is configured to heat the solid source 88 provided in the liquid source storage member 66 such that the solid source 88 has wettability. Further, the heating device 68 is also configured to heat the leading end of the source containing body 64 to an evaporating temperature of the liquid source 88A. The heating device 68 is provided within the source containing body 64. To elaborate, the heating device 68 includes a first heater 92 corresponding to the liquid source storage member 66 and a second heater 94 corresponding to the leading end of the source containing body 64. Each of the first and second heaters 92 and 94 may be a resistance heater such as a carbon wire heater and is embedded in the source containing body 64.

The first heater 92 heats the solid source 88 to a temperature such the solid source 88 has wettability, and the second heater 94 heats the liquid source 88A to a higher temperature such that the liquid source 88A is evaporated. Accordingly, there is generated a temperature gradient in which a temperature of the liquid source flow surface 90 increases toward a lower portion thereof. Here, it may be possible to additionally provide a single heater or multiple heaters between the first and second heaters 92 and 94 and to generate a temperature gradient in which the temperature of the liquid source flow surface 90 increases gradually toward the lower portion thereof.

The first and second heaters 92 and 94 are connected with a temperature controller 100 via power feed lines 96 and 98, respectively. Further, in the source containing body 64, a first temperature measuring device 102 is provided so as to correspond to the liquid source storage member 66, and a second temperature measuring device 104 is provided so as to correspond to the leading end of the source containing body 64. Measurement values of the first and second temperature measuring devices 102 and 104 are sent to the temperature controller 100. By way of example, each of the first and second temperature measuring devices 102 and 104 may be composed of thermocouples.

Based on measurement values of the first and second temperature measuring devices 102 and 104, the temperature controller 100 controls the first heater 92 to adjust a flowing amount of the liquid source 88A from the liquid source storage member 66, and controls the second heater 94 to adjust an evaporating amount of the liquid source 88A from the liquid source flow surface 90.

An overall operation of the film forming apparatus 2 configured as described above is controlled by an apparatus controller 106 including, e.g., a computer. A computer program for implementing such an operation is stored in a storage medium 108. The storage medium 108 may be, but not limited to, a flexible disk, a CD (Compact Disk), a hard disk, a flash memory, or a DVD. To be specific, operation of the source supplying apparatus 62, start and stop of the supply of the gas, a flow rate of the gas, a processing temperature or a processing pressure, and the like are controlled in response to instructions from the apparatus controller 106.

Further, the apparatus controller 106 has a user interface (not shown) connected thereto. The user interface includes a keyboard through which an operator inputs or outputs a command to manage the apparatus, a display for visually displaying an operational status of the apparatus, and the like. Further, it may be also possible to perform communications for each operation to the apparatus controller 106 via a communications line.

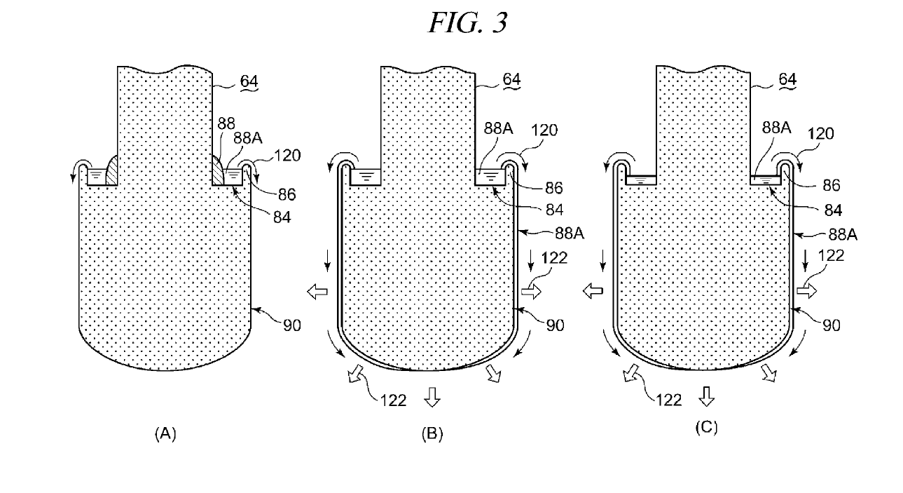

Now, an operation of the film forming apparatus using the source supplying apparatus having the above-described configuration in accordance with the illustrative embodiment will be explained with reference to FIG. 3. FIG. 3 is an enlarged cross sectional view illustrating the source containing body (illustration of heaters and thermocouples are omitted) of the source supplying apparatus in accordance with the illustrative embodiment. First, an unprocessed semiconductor wafer W is held on a non-illustrated transfer arm. After the gate valve 48 at the sidewall of the processing chamber 4 is opened, the semiconductor wafer W is loaded into the processing chamber 4 through the loading/unloading port 46. Then, by operating the lifter device 24 provided under the mounting table 12, the wafer W is received by the lifer pins 26 and mounted on the mounting table 12. In the present illustrative embodiment, a silicon substrate having a diameter of, e.g., about 300 mm is used as the wafer W. Here, the wafer W is mounted in a so-called face-up state such that a film forming target surface of the wafer W faces upward.

The source supplying apparatus 62 is mounted to the ceiling of the processing chamber 4 in advance, and a solid source 88 is stored in the liquid source storing recess 84 of the liquid source storage member 66 of the source containing body 64 (see FIG. 3(A)). By way of non-limiting example, gallium (Ga) in a solid phase is stored as the solid source 88. The gallium (Ga) in the solid phase starts to melt at a temperature of about 30° C. and starts to evaporate at a temperature of about 500° C.

In this state, the exhaust system 38 is continuously driven. As a result, the inside of the processing chamber 4 is evacuated to vacuum. Power is fed to the processing target object heating unit 14 within the mounting table 12. Therefore, a temperature of the semiconductor wafer W mounted on the mounting table 12 is raised to and maintained at a certain processing temperature. Further, a N₂ gas serving as a source gas is introduced into the processing chamber 4 from the source gas introducing device 50 while a flow rate of the source gas is controlled.

At the same time, in the source supplying apparatus 62, the temperature controller 100 feeds power to the first heater 92 and the second heater 94 of the heating device 68, so that the source containing body 64 is heated. A temperature of the source containing body 64 is constantly detected by the first and second temperature measuring devices 102 and 104, and is inputted to the temperature controller 100. If the temperature of the source containing body 64 increases, the solid source 88, which is stored in the liquid source storage member 66 in advance, melts gradually and turns into the liquid source 88A (see FIG. 3(A)).

If the solid source 88 melts to become the liquid source 88A, the liquid source 88A has wettability and flows out over the liquid source storage dam 86 of the liquid source storing recess 84, as indicated by arrows 120 in FIG. 3(A), and starts to flow gradually on the liquid source flow surface 90, i.e., on the outer peripheral surface of the source containing body 64, as shown in FIG. 3(B). While the liquid source 88A flows on the liquid source flow surface 90, the liquid source 88A is evaporated or diffused little by little, as indicated by arrows 122. Here, since wettability of the liquid source 88A varies depending on temperature, the first heater 92 is controlled so as to adjust a flowing amount of the liquid source 88A from the liquid source storage member 66. Further, the second heater 94 is controlled so as to adjust an evaporating amount of the liquid source 88A from the liquid source flow surface 90.

In the illustrative embodiment, the liquid source flow surface 90 has a temperature gradient in which the temperature thereof increases toward a lower portion thereof. Accordingly, as the liquid source 88A approaches the lower portion of the liquid source flow surface 90, the evaporating amount of the liquid source 88A increases. Here, it may be also possible not to make the above-described temperature gradient on the liquid source flow surface 90 but to set the entire liquid source flow surface 90 to have a temperature equal to or higher than an evaporating temperature of the liquid source 88A. Evaporated gallium (Ga) and nitrogen (N) gas make a reaction on a surface of the wafer W heated to a high temperature, so that a thin film of the compound semiconductor made of gallium nitride (GaN) is gradually grown epitaxially on the surface of the wafer W.

At this time, as stated above, the temperatures of the first heater 92 and the second heater 94 are controlled independently, so that the flowing amount of the liquid source 88A from the liquid source storage member 66 and the evaporating amount of the liquid source 88A from the liquid source flow surface 90 are in balance. Accordingly, the liquid source 88A can be prevented from dripping down as droplets from a lower end portion of the liquid source flow surface 90. Further, if a liquid surface is lowered due to a reduced amount of the liquid source 88A in the liquid source storage member 66 as depicted in FIG. 3(C), the heating temperature of the first heater 92 is gradually increased. Thus, as stated above, since wettability of the liquid source 88A improves with the rise of temperature, it is possible to control the liquid source 88A to flow at a stable flow rate.

As for processing conditions, an internal pressure of the processing chamber 4 is set to be about 10⁻¹⁰ to about 10⁻² Torr. Meanwhile, a temperature of the mounting table 12 is set to be in the range of, e.g., about 800° C. to about 1200° C., which depends on a kind of a compound semiconductor to be formed. Especially, when GaN is formed, the temperature of the mounting table 12 is set to be in the range of, e.g., about 850° C. to about 1100° C. Further, a temperature of the liquid source storage member 66 heated by the first heater 92 is set to be in the range of, e.g., about 400° C. to about 850° C., which also depends on a kind of the liquid source 88A. Especially, when Ga is used as a source, the temperature of the liquid source storage member 66 is set to be in the range of, e.g., about 500° C. to about 650° C. Further, a temperature of the leading end of the source containing body 64 heated by the second heater 94 is set to be in the range of, e.g., about 900° C. to about 1100° C., which also depends on a kind of the liquid source 88A. Especially, when Ga is used as a source, the temperature of the leading end of the source containing body 64 is set to be in the range of, e.g., about 1000° C. to about 1080° C.

Further, if the amount of the solid source 88 provided in the liquid source storage member 66 is reduced, the source containing body 64 can be taken out in an upward direction by separating the bolts 80 that hold the source containing body 64, and then, the solid source 88 may be replenished.

In accordance with the illustrative embodiment as described above, the liquid source 88A stored in the liquid source storage member 66 of the vertically elongated source containing body 64 flows on the liquid source flow surface 90 by its wettability toward the leading end of the source containing body 64. Accordingly, without the complicate structure of the apparatus, the liquid source 88A can be evaporated or diffused from the leading end of the source containing body 64 while being prevented from dripping down as droplets. Furthermore, since the film forming apparatus 2 is configured to use the source supplying apparatus 62, it is possible to form a thin film of a compound semiconductor on a processing target object, e.g., a semiconductor wafer by a MBE method while maintaining the wafer in a face-up state.

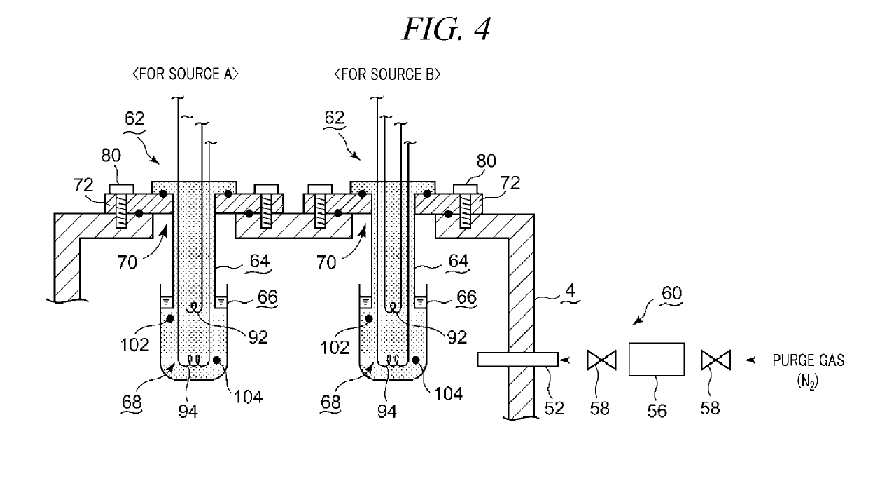

In the above-described illustrated embodiment, gallium (Ga), which is a solid at a room temperature (25° C.), is used as the solid source 88. However, the solid source may not be limited thereto and the illustrative embodiment may also be applicable to a case where the source is in a liquid phase at a room temperature (25° C.). In such a case, a liquid source may be provided in the liquid source storage member 66 from the beginning of the film forming process. Further, although the illustrative embodiment has been described for the case where one of two kinds of elements composing the compound semiconductor is a solid or a liquid at a room temperature while the other is a gas, such as N₂, the illustrative embodiment may not be limited thereto and may also be applicable to a case where the two kinds of elements are all solids or liquids at a room temperature. Further, the two kinds of elements may be a combination of a solid and a liquid. In such a case, two source supplying apparatuses 62 may be provided. FIG. 4 is a partial configuration view illustrating a part of a modification example of such a film forming apparatus. In FIG. 4, like parts described in FIGS. 1 and 2 are assigned the same reference numerals, and redundant description thereof will be omitted.

As depicted in FIG. 4, two source supplying apparatuses 62 are installed at a ceiling of a processing chamber 4. Then, different sources, e.g., sources A and B, are provided in the respective source supplying apparatuses 62. In this case, since nitrogen (N) is not used as the source, a source gas introducing device 50 in FIG. 1 only serves as a purge gas introducing device 60 in FIG. 4. Moreover, temperatures of the two source supplying apparatuses 62 are controlled individually depending on the kinds of the source provided therein. Such temperature control is performed by a temperature controller 100 (see FIG. 1). Further, when nitrogen is used as a source, the purge gas introducing device 60 may also serve as the source gas introducing device 50. Furthermore, the purge gas introducing device 60 may also serve as a source gas introducing device 50 for introducing a source gas containing two or more kinds of elements, not limited to nitrogen.

In addition, when three or more kinds of elements are used to form a compound semiconductor, the number of source supplying apparatuses 62 may be increased according to the number of the elements. Further, in the above-described illustrative embodiment, although GaN, which is a binary compound containing two kinds of elements, is formed as a thin film of a compound semiconductor, the illustrative embodiment is not be limited thereto and may also be applicable to a case of forming a thin film of other binary compound semiconductor such as InN, GaAs, AlAs, GaSb, InP, InAs, or InSb.

Further, the compound semiconductor may not be limited to the binary compound, and the illustrative embodiment is also applicable to a case of forming a thin film of a multi-elements (three elements or more) compound semiconductor such as AlGaAs, AlInP, GalnP, or AlGaPAs.

Moreover, in the above-described illustrative embodiment, a semiconductor wafer is used as a processing target object. Here, the semiconductor wafer includes a silicon substrate and a compound semiconductor substrate such as sapphire (Al₂O₃), GaAs, SiC, or GaN. Furthermore, the processing target object is not limited to the semiconductor wafer but may be a glass substrate, a ceramic substrate, or the like.

What is claimed is:

1. A source supplying apparatus for supplying a source used for forming a compound semiconductor, the apparatus comprising:
a vertically elongated source containing body having an outer peripheral surface formed as a liquid source flow surface capable of allowing a liquid source to flow thereon;
a liquid source storage member provided at a position of the source containing body in a height direction to store therein the liquid source, and configured to allow the liquid source to flow to the liquid source flow surface by wettability; and
a heating device provided within the source containing body, and configured to heat the liquid source storage member so as to allow the liquid source to have wettability and to heat a leading end of the source containing body to an evaporating temperature of the liquid source.

2. The source supplying apparatus of claim 1, wherein the liquid source storage member comprises:
a liquid source storing recess formed along a periphery of the source containing body; and
a liquid source storage dam protruded upward from an outer peripheral end of the liquid source storing recess.

3. The source supplying apparatus of claim 1, wherein the heating device comprises:
a first heater provided at a position corresponding to the liquid source storage member; and
a second heater provided at a position corresponding to the leading end of the source containing body.

4. The source supplying apparatus of claim 1, wherein the heating device comprises a temperature controller, and
the temperature controller is configured to control the first heater so as to adjust a flowing amount of the liquid source from the liquid source storage member and to control the second heater so as to adjust an evaporating amount of the liquid source from the liquid source flow surface.

5. The source supplying apparatus of claim 1, wherein the source containing body is made of ceramic or quartz.

6. The source supplying apparatus of claim 1, wherein the source is in a solid phase or a liquid phase at a temperature of about 25° C.

7. A film forming apparatus for forming, on a surface of a processing target object, a thin film of a compound semiconductor containing plural kinds of elements, the apparatus comprising:
an evacuable processing chamber;
a holding device for holding the processing target object in a face-up state within the processing chamber;
a heating device configured to heat the processing target object; and
a single or a plurality of source supplying apparatuses as claimed in claim 1.

8. The film forming apparatus of claim 7, further comprising:
a source gas introducing device configured to introduce into the processing chamber a source gas containing one or more kinds of elements.

9. The film forming apparatus of claim 7, wherein the thin film contains two kinds of elements selected from a group consisting of Ga, In, As, and N.
